(19) United States
(12) Patent Application Publication
(10) Pub. No.: US 2006/0098507 A1
(43) Pub. Date: May 11, 2006

(54) BRIDGING CIRCUIT

(76) Inventor: Ching-Fu Hung, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,050

(22) Filed: Oct. 3, 2005

(30) Foreign Application Priority Data
Nov. 5, 2004 (TW) 93133766

(51) Int. Cl. G11C 7/00

(52) U.S. Cl. 365/202

(57) ABSTRACT

A bridging circuit is provided. The bridging circuit includes a USB interface, a USB host, a memory card interface, a buffer and a microprocessor controller. The USB host reads data from and outputs data to a USB device via the USB interface. The memory card interface reads data from and outputs data to a system device. The buffer stores the data from the USB host and/or the memory card interface. The microprocessor controller outputs control signals to the USB host, the buffer and the memory card interface to mediate the data transmission between the USB host, the buffer and the memory card interface.

### CROSS-REFERENCE TO RELATED APPLICATION

This application claims the priority benefit of Taiwan application serial no. 93133766, filed on Nov. 5, 2004. All disclosure of the Taiwan application is incorporated herein by reference.

### BACKGROUND OF THE INVENTION

1. Field of the Invention

The present invention relates to a data exchange device. More particularly, the present invention relates to a bridging circuit.

2. Description of the Related Art

In a society demanding very high speed information exchange, storage devices that are energy efficient, portable and easy to use are increasingly important. Storage devices that meet the above conditions include memory cards fabricated from flash memory and mobile discs.

Because a memory card has an easy-to-fabricate interface, most voice devices such as the moderately priced MP3 player or DVD player have an additional memory card interface. However, most memory cards currently in the market uses a variety of interface specifications and hence there is not a single universally accepted standard. Therefore, the memory cards users had for their mobile phones, digital cameras or multimedia players cannot be interchanged because of their different in interface specifications. This is a tremendous waste of money for the users of these electronic products.

To prevent this type of resource wastage, a universal serial bus (USB) is often deployed as an interface for data transmission. However, because a flash disc is itself a USB slave device, the flash disc can only be used in a device having a USB host. Yet, a USB host is a complicated and expensive piece of equipment. Therefore, it is difficult for a manufacturer to implement a USB host inside a relatively cheap product. Furthermore, even if the manufacturer has decided to integrate a USB host into a particular product, the challenge for integrating the USB host chip with a driving program and changing the original hardware design is quite large. Moreover, considerable time must be spent to test overall compatibility of the product. All in all, the design is very time consuming and costly.

### SUMMARY OF THE INVENTION

Accordingly, at least one objective of the present invention is to provide a bridging circuit such that an electronic apparatus having a memory card interface can communicate with a universal serial bus (USB) device.

To achieve these and other advantages and in accordance with the purpose of the invention, as embodied and broadly described herein, the invention provides a bridging circuit comprising a universal serial bus (USB) host controller, a USB interface, a memory card interface, a buffer and a microprocessor controller. The USB host controller communicates with a universal serial bus (USB) device through the USB interface. The memory card interface is used for coupling to the memory card interface. The buffer is connected to the USB host controller and the memory card interface for storing the data transmitted from the USB host controller and/or the memory card interface. The microprocessor controller is electrically coupled to the USB host controller, the buffer and the memory card interface for outputting control signals to control the operation of these devices.

According the aforementioned technique, the USB host can easily communicate with existing memory card interface on a device so that the difficulty of implementing a USB host is very much simplified.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a block diagram of bridging circuit for a universal serial bus (USB) host and a memory card according to one preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

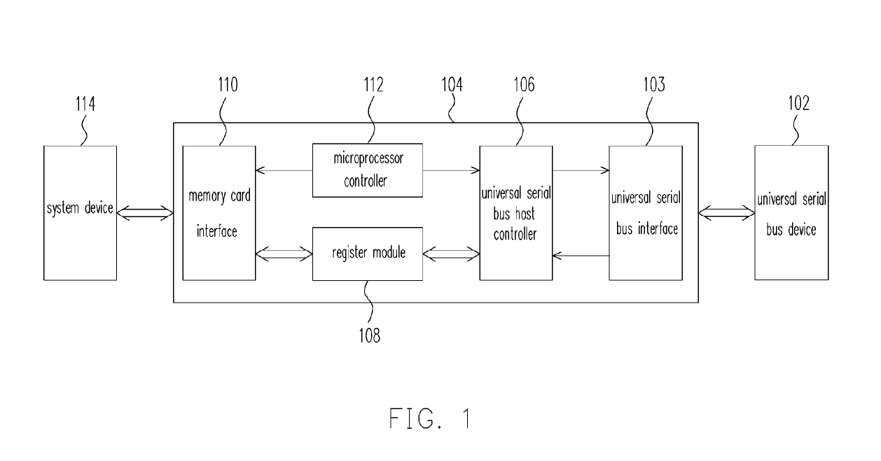

FIG. 1 is a block diagram of bridging circuit according to one preferred embodiment of the present invention. When the USB device 102 connects with the bridging circuit 104, a microprocessor controller 112 inside the bridging circuit 104 will transmit related information to a USB host controller 106 inside the bridging circuit 104. Then the USB host controller 106 take control of the data transmission between the USB device 102 and the bridging circuit 104 via the USB interface 103. The USB device 102 can be a USB slave device, for example a flash disk or a card reader.

The data from the USB device 102 will be stored into a register module 108 (for example, a buffer) by USB host controller 106. Then the data stored in the register module 108 will be retrieved and transmitted to a system device 114 through the memory card interface 110. The memory card interface 110 can be the interface of a compact flash card (a CF card), the interface of a secure digital card (a SD card), the interface of a multimedia card (a MM card), the interface of a smart media card (a SM card), the interface of a memory stick card (a MS card) or the interface of an xD picture card (an xD card), for example.

On the other hand, the system device 114 can transmit data to the register module 108 through the memory card interface 110. Then, the USB host controller 106 can retrieve the data from the register module 108 and transmitted the retrieved data to the USB device 102 via the USB interface 103.

Aside from flash disc, card reader and digital camera, other large storage capacity devices such as USB hard discs or flash discs with MP3 function that meet the USB transmission interface standard can utilize the techniques in the present invention to facilitate the operation of a conventional system device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bridging circuit, comprising:
a universal serial bus interface;
a universal serial bus host controller for reading data from a universal serial bus device and outputting data to the universal serial bus device via the universal serial bus interface;
a memory card interface for coupling with a system device;
a register module electrically coupled to the universal serial bus host controller and the memory card interface for storing data transmitted through the universal serial bus host controller and the memory card interface; and
a microprocessor controller electrically coupled to the universal serial bus host controller, the register module and the memory card interface for controling the operation of the universal serial bus host controller, the register module and the memory card interface.

2. The bridging circuit of claim 1, wherein the memory card interface comprises an interface of a compact flash memory.

3. The bridging circuit of claim 1, wherein the memory card interface comprises an interface of a secure digital card.

4. The bridging circuit of claim 1, wherein the memory card interface comprises an interface of a multimedia card.

5. The bridging circuit of claim 1, wherein the memory card interface comprises an interface of a smart media card.

6. The bridging circuit of claim 1, wherein the memory card interface comprises an interface of a memory stick card.

7. The bridging circuit of claim 1, wherein the memory card interface comprises an interface of an xD picture card.
